(19) United States
(12) Patent Application Publication
(10) Pub. No.: US 2004/0110499 A1
(43) Pub. Date: Jun. 10, 2004

(54) Flow control apparatus and method for wireless communication system

(76) Inventors: Chul-Hee Kang, Gyeonggi-Do (KR); Sun Ju Lim, Seoul (KR)

Correspondence Address: FLESHNER & KIM, LLP, P.O. Box 221200, Chantilly, VA, 20153-1200, US

(21) Appl. No.: 10/392,304

(22) Filed: Mar. 20, 2003

(30) Foreign Application Priority Data
Mar. 21, 2002 (KR) 15228/2002

(51) Int. Cl. G06F 15/173; H04L 1/00; H04J 1/16; H04J 3/14; G06F 11/00; H04L 12/26; G08C 15/00; G01R 31/08

(52) U.S. Cl. 455/422.1; 370/236; 370/230.1; 709/226

(57) ABSTRACT

A flow control apparatus for a mobile communication system includes a traffic type recognition module which interfaces with an upper layer and determines a traffic type of data from the upper layer, a flow control module which controls flow of the data based on the traffic type determined by the traffic type recognition module, and a lower layer interface module which allows the flow control apparatus to communicate the data with an AAL5 Adaptation Layer. The traffic type recognition module delivers the data to the flow control module when the traffic type of the data is a loss sensitive type and directly transfer the data to the AAL5 when the traffic type of the data is a real time sensitive type. Also, a sliding window control algorithm may be used to control the transmission/reception of data based on, for example, a voice-data ratio.

### BACKGROUND OF THE INVENTION

1. Field of the Invention

The present invention relates to wireless communication systems and, in particular, to a flow control apparatus and method for wireless communication system.

2. Background of the Related Art

Asynchronous Transfer Mode (ATM) was developed specifically to improve transport and switching in wide area networks (WANs). In particular, ATM is optimized for transporting multiple classes of information (i.e., voice, data, video) simultaneously with great efficiency, even when all of these traffic types are sent in bursts. These are the same goals of 3 G wireless networks. 3 GPP has standardized on ATM (AAL5) as the control plane solution for signal transmission.

Typically, ATM transmits broadband information using fixed length, relatively small, 53 -byte cells suitable for carrying both constant rate data as well as burst data. ATM evolved from the Broadband Integrated Services Digital Network (B-ISDN) standard, which is an extension of ISDN. B-ISDN utilizes a 7 layer reference model similar to the Open Systems Interconnection (OSI) 7 layer architecture. ATM redefines the lower three layers, i.e., the Physical Layer, the ATM Layer, and the ATM Adaptation Layer (AAL).

The Physical Layer is divided into sub-layers: the Physical Medium sub-layer (PMD) which handles processing specific to a particular physical layer such as transmission rate, clock extractions, and so on, and the Transmission Convergence sub-layer (TC) which extracts information content from the physical layer data format.

The ATM layer processes ATM cells. An ATM cell consists of a 5-byte header and a 48-byte payload. The header contains the ATM cell address and other control information.

The ATM Adaptation Layer consists of two sub-layers: Convergence sub-layer (CS) and Segmentation and Reassembly sub-layer (SAR).

Data is received from the various upper layer applications by the Convergence sub-layer and mapped into the Segmentation and Reassembly sub-layer. User information, typically of variable length, is packetized into data packets called Convergence Sub-Layer Protocol Data Units (CS-PDUs). depending on the Adaptation Layer, these variable length CS-PDUs will have a short header, trailer, a small amount of padding, and may have a checksum.

The Segmentation and Reassembly Sub-Layer receives the CS-PDUs from the Convergence Sub-Layer and segments them into one or more 48-byte SAR-PDU, which can be carried in the 48-byte ATM information payload bucket. The SAR-PDU maps directly into the 48-byte ATM-information payload bucket. The SAR-PDU maps directly into the 48-byte payload of the ATM cell transmitted by the Physical Layer.

Also, the ATM Adaptation Layer (AAL) has a function to receive the data from the various sources or applications and converts the data to 48-byte segments that will fit into the payload of an ATM cell. Since ATM benefits from its ability to accommodate data from various sources with different characteristics, the Adaptation Layer must be flexible.

The traffic from the various sources have been categorized by the standards committees into four general classifications, Class A through Class D. Initially, four different adaptation layers (AAL1 through AAL4) were envisioned for the four classes of the traffic. However, since the AAL3 and AAL4 both could carry Class C and Class D traffic and since the differences between AAL3 and AAL4 are so slight, the two have been combined into one AAL3/4.

AAL3/4 is quite complex and carries a considerable overhead. Therefore, a fifth Adaptation Layer, AAL5, has been adopted for carrying Class C traffic, which is simpler and eliminates much of the overhead of the proposed AAL3/4. AAL5 is referred to as the Simpler and Efficient Adaptation Layer or SEAL.

3 GPP has mandated that ATM, with its low latency characteristics, be deployed as the bearer service protocol for 3 G networks, especially when delivering real-time sensitive payloads such as voice and video. AAL2 and AAL5 are adopted for data delivery in respective circuit switched and packet switched connections.

With the advance of ATM, Transmission Control Protocol (TCP) is widely used as a higher layer protocol to guarantee reliable data transmission over ATM networks.

There are some flow control protocols implemented in the TCP. One is the Stop-and-Wait protocol. In the Stop-and-Wait protocol, the sender cannot transmit a new packet until the acknowledgement (ACK) for the last one sent is received. The transmission speed is automatically adjusted to both the speed of the network and the rate the receiver sends new acknowledgements. However, the Stop-and-Wait protocol becomes rather inefficient if the path connecting the sender and receiver has a large bandwidth (see FIG 1a).

To solve this problem, a sliding window algorithm (Go-back-N continuous ARQ) is developed, in which a window is the maximum amount of data that can be sent without having to wait for ACK. That is, the sender transmits all the new segments in the window and waits for acknowledgement(s) to come. The window slides to the indicated position and set the window size to the value advertised in the acknowledgement. When the sender waits for an acknowledgement to a segment and it does not arrive for a predetermined period, the segment is retransmitted. When the acknowledgement arrives, it causes the window to be repositioned and transmission continues from the segment following the last one transmitted (see FIG. 1b).

Another strategy is to resend only the segments that are actually lost and damaged. The receiver buffers all the segments after the lost one. When the sender finally noticed the problem (e.g. no ACK for the lost segment is received with timeout limit), the sender retransmits the segment in question. This is called selective repeat algorithm (see FIG. 1c).

In a wireless communication system which has adopted AAL5 as the control plane protocol for data transmission, real-time sensitive voice and loss sensitive data services are simultaneously supported. However, flow control is required only for the loss sensitive data service, not for real-time sensitive voice service.

However, adopting the TCP as the upper layer protocol of AAL5 only for guaranteeing reliability of the loss sensitive data service causes waste of resources due to the TCP overhead, especially when the data traffic amount is smaller than that of voice traffic. This results in system performance degradation. Also, even after the TCP over ATM network is actually implemented, it is difficult to troubleshoot problems such as breakage of the communication link due to the hardware complexity of the network.

### SUMMARY OF THE INVENTION

An object of the invention is to solve at least the above problems and/or disadvantages and to provide at least the advantages described hereinafter.

It is an object of the present invention to provide a flow control apparatus and method for wireless communication system using AAL5 as the adaptation layer, which is capable of enhancing system performance by selectively performing flow control function according to the service type.

It is another object of the present invention to provide a flow control apparatus and method for wireless communication system using AAL5 as the adaptation layer, which is capable of efficiently controlling traffic flow even when the data traffic amount is smaller than the voice traffic amount, by flexibly controlling the sliding window.

It is still another object of the present invention to provide a flow control apparatus and method for wireless communication system using AAL5 as the Adaptation Layer, which is capable of quickly troubleshooting the network problems such as link breakage and malfunction of the system by the sliding window management.

To achieve the above objects, the flow control apparatus of the present invention comprises a traffic type recognition module which interfaces with an upper layer and distinguishes traffic type of payload from the upper layer, a flow control module which controls flow of the payload from the traffic type recognition module, a lower layer interface module which interfaces with a lower layer.

The traffic type recognition module delivers the payload to the flow control module when the traffic type of the payload is a first traffic type and directly transfer the payload to the lower layer when the traffic type of the payload is a second traffic type.

The first traffic type is loss sensitive type such as a data-based payload and the second traffic type is real time sensitive type such as a voice- or video-based payload.

The flow control module controls the traffic flow based on a modified sliding window algorithm.

The flow control module includes a transmission buffer which temporarily stores the payload from the upper layer until receiving an acknowledgement in response to the previously transmitted payload, a transmission window which adjusts transmission amount of the payload, a reception buffer which temporarily stores received payloads until an upper layer data unit is completed with the received payloads, a reception window which adjusts reception amount of the payload, a window management module which controls the transmission buffer, transmission window, reception buffer, and reception window in consideration of network state.

The window management module periodically checks the states of the transmission and reception windows and transmits system messages according to the states of both the transmission and reception windows. The state of the window is one of a ready state, pending state, and dead state.

The window management module controls such that the payload is transmitted when the transmission window is in the ready state. The window management module periodically generates and transmit an acknowledgement request message when the transmission window is in the pending state. The transmission window enters the ready state when an acknowledgement message is received in response to the acknowledgement request message. The window management module periodical generates and transmits a check message. The transmission window is reinitialized when an echo-back message is received in response to the check message.

To achieve the above objects, in the flow control method for mobile communication system adopted AAL5 as an Adaptation Layer, the flow control apparatus receives data from upper layers, checks a traffic type of the data, and controls transmission of the data according to the traffic type of the data.

The traffic type is one of real time sensitive type and loss sensitive type.

The flow control apparatus forwards the data to the AAL5 when the traffic type of the data is real time sensitive and enters a flow control procedure when the traffic type of the data is loss sensitive.

The flow control procedure includes initializing a sliding window, checking a state of the sliding window, and adjusting the data transmission according to the state of the sliding window.

The data transmission adjusting step includes transmitting the data in unit of segment with unique sequence number when the sliding window is in a ready state. The sliding window maintains the ready state when an ACK/NACK message in response to a previously transmitted segment is received in a first timeout.

The data transmission adjusting step further includes transmitting ACK/NACK request message when the sliding window is in a pending state. The sliding window enters the pending state when an ACK/NACK message in response to a previously transmitted segment is not received in the first timeout.

The data transmission adjusting step further includes transmitting a check message when the sliding window is in a dead state. The sliding window enters the dead state when an ACK/NACK message in response to the ACK/NACK request message is not received in a second timeout.

The sliding window is reinitialized when an echo-back message in response to the check message is received in the second timeout.

Additional advantages, objects, and features of the invention will be set forth in part in the description which follows and in part will become apparent to those having ordinary skill in the art upon examination of the following or may be learned from practice of the invention. The objects and advantages of the invention may be realized and attained as particularly pointed out in the appended claims.

### BRIEF DESCRIPTION OF THE DRAWINGS

The invention will be described in detail with reference to the following drawings in which like reference numerals refer to like elements wherein:

FIG 1a is a conceptual view illustrating a stop-and-wait ARQ algorithm for flow control;

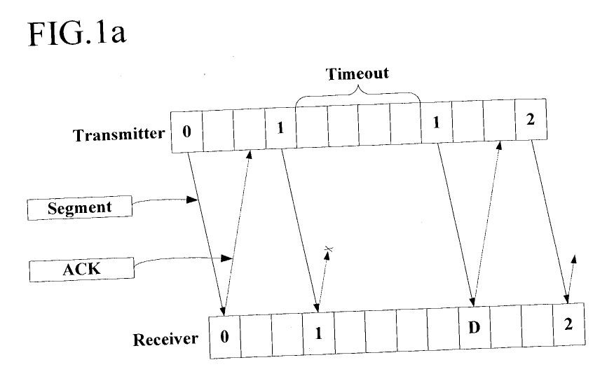

FIG. 1b is a conceptual view illustrating a Go-back-N continuous ARQ algorithm for flow control;

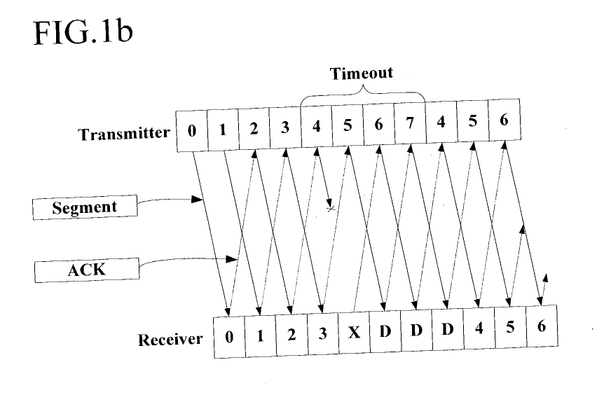

FIG. 1c is a conceptual view illustrating a selective repeat algorithm for flow control;

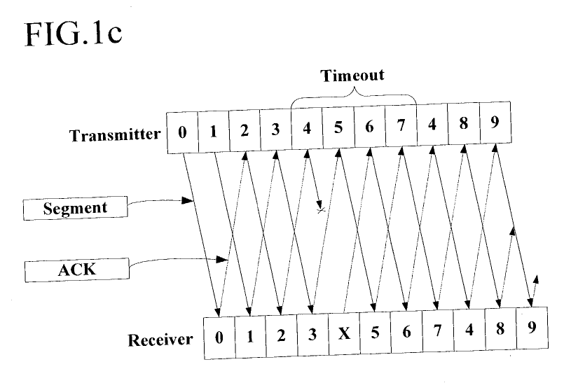

FIG. 2 is a block diagram illustrating a protocol stack adopted AAL 5 as Adaptation Layer for a mobile communication system according to the present invention;

FIG. 3 is a conceptual view illustrating a flow control function of FIG. 2;

FIG. 4 is a conceptual view illustrating a state model of the window of FIG. 3;

FIG. 5 is a flowchart illustrating a flow control method for wireless communication system using AAL5 according to the present invention; and

FIG. 6 is a flowchart illustrating the flow control procedure of FIG. 5.

### DETAILED DESCRIPTION OF PREFERRED EMBODIMENTS

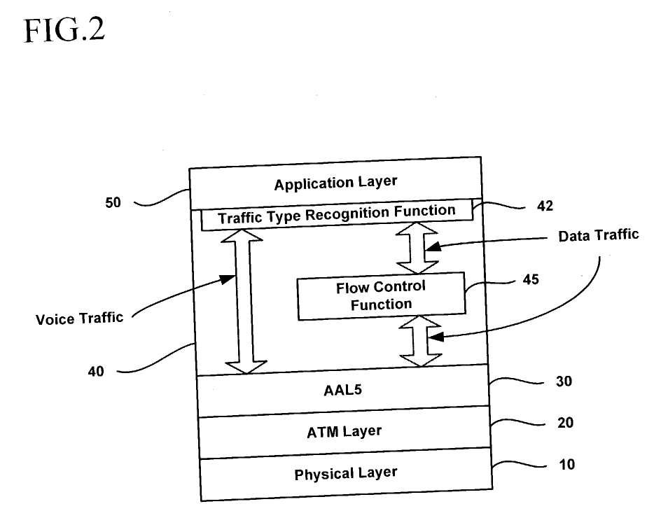

FIG. 2 is a block diagram illustrating a protocol stack adopting AAL 5 as the Adaptation Layer of a mobile communication system according to a preferred embodiment of the present invention. The protocol stack includes a physical layer 10, ATM layer 20, AAL5 30 as ATM Adaptation Layer, transport layer 40, and application layer 50. This protocol stack is similar to a typical ATM network protocol and thus well-known functions or constructions are not described in detail.

The transport layer 40 is provided with a traffic-type recognition function 42 and a flow control function 45. The traffic type recognition function 42 checks the traffic from the application layer 50 and AAL5 30 and determines whether or not the traffic is real-time sensitive (voice) or loss sensitive (data).

If the traffic from the application layer 50 or the AAL5 30 is real-time sensitive voice, the traffic type recognition function 42 of the transport layer 40 bypasses the flow control function 45 when sending real-time sensitive voice from the upper layer to the AAL5 30 and also bypasses function 45 when sending the real-time sensitive voice from the lower layer to the application layer 50. On the other hand, if the traffic from the application layer 50 or the AAL5 30 is loss sensitive data, the traffic-type recognition function delivers the data traffic to the flow control function 45. The traffic-type recognition function 42 preferably identifies the type of traffic based on header information of a transport layer data unit. The header information may, for example be a source port number, upper layer application, or data class carried by an associated field of the header of the transport layer data unit. The flow control function 45 guarantees reliable data transmission and operates with an enhanced sliding window algorithm.

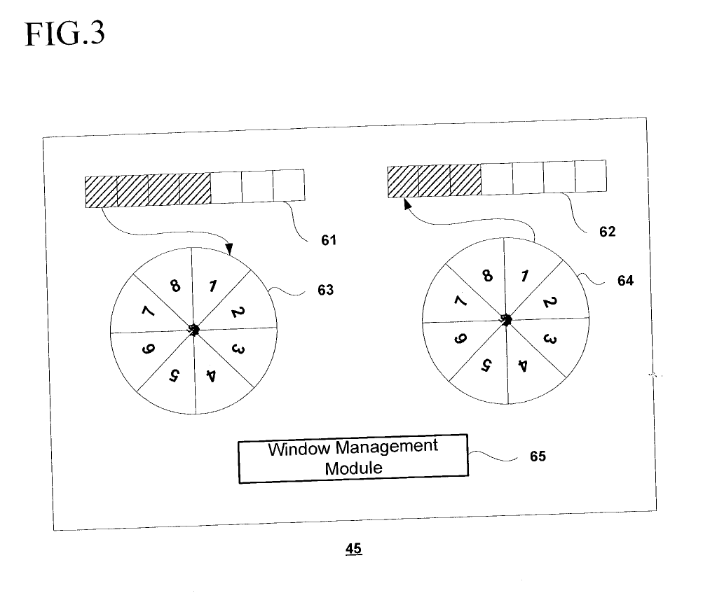

FIG. 3 is a conceptual view illustrating the flow control function of FIG. 2. Function 45 includes a transmission buffer 61 for temporarily storing the data to be transmitted until receiving an acknowledgement in response to the previously transmitted data, a transmission window 63 for controlling the data transmission, a reception buffer 62 for temporarily storing received data until an upper layer data unit is completed with the received data, a reception window 64 for controlling the data reception, and a window management module 65 which monitors the network and manages the transmission window 63 and reception window 64 according to the traffic environment.

The transmission buffer 61 stores duplicates of the transmitted segments. Flow control function 45 discards the duplicate of the segment when an acknowledgement (ACK) corresponding to the segment is received and retransmits the segment when an negative acknowledgement (NACK) corresponding to the segment is received.

The reception buffer 62 stores the segments until an upper layer data unit is complete. Flow control function 45 discards the segment which is already received and requests retransmission when a segment belonged to the upper layer data unit is not received. If the upper layer data unit is complete, the flow control function 45 delivers the upper layer data unit to the upper layer.

The transmission window 63 has a predetermined number of slides and for illustrative purposes 8 slides are shown. Each slide is closed when the segment is transmitted therethrough. Also, each slide knows where the duplicate of the segment is located in the transmission buffer 61, such that when an associated NACK is received from the receiver the duplicate is retransmitted through the associated slide.

The reception window 64 also has a predetermined number of slides and for illustrative purposes only 8 slides are shown. Each slide is closed when the segment is received therethrough and is opened when an acknowledgement is transmitted therethrough.

The window management module 65 periodically checks the states of the transmission and reception windows 63 and 64 so as to transmit system messages to network elements directly connected thereto according to the states of the windows 63 and 64.

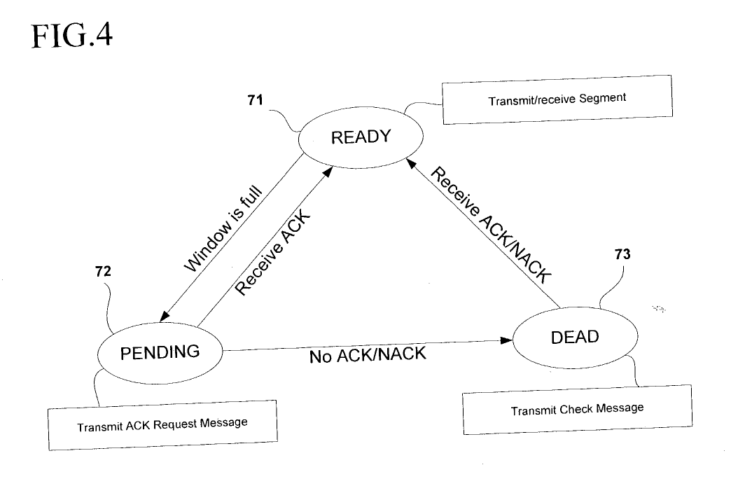

FIG. 4 is a conceptual view illustrating a state model of the window of FIG. 3. In this embodiment, the window is in one of three states: a ready state, a pending state, and a dead state.

In the ready state 71, data is exchanged between the transmitter and receiver. This may be accomplished by having the transmitter transfer a number of segments preferably equal to as much as the window size can accommodate, as long as acknowledgements are received in response to the transmitted segments. If the transmitter does not receive one or more acknowledgements from the receiver after transmitting the segments as much as the window size can accommodate in the ready state 71, the transmission window enters the pending state 72.

In the pending state 72, the transmission window is full such that the transmitter does not transmit further segments and waits for receiving the acknowledgements in response to the previously transmitted segments. If the acknowledgement message is not received within a predetermined timeout limit, the window management module 65 periodically transmits an acknowledgement request message to the receiver such that the receiver transmits an ACK or NACK corresponding to the segment indicated by the acknowledgement request message. If the transmitter receives the ACK/NACK in response to the acknowledgement request message, the transmission window enters the ready state 71. On the other hand, if the transmitter does not receive the ACK/NACK within a predetermined timeout limit, the transmission window enters the dead state 73.

In the dead state 73, the window management module 65 periodically transmits a check message for the purpose of checking whether or not the data link to the receiver is recovered. If an ACK/NACK message is received in response to the check message, the transmission window enters the ready state 71 so as to restart the data transmission.

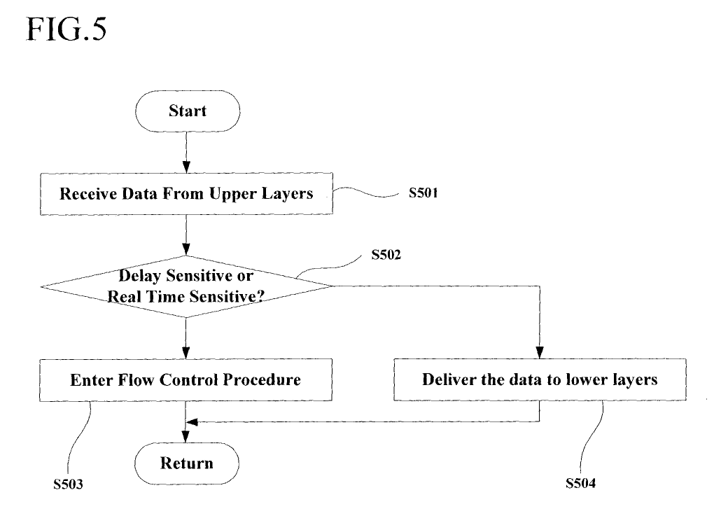

FIG. 5 is a flowchart illustrating a flow control method for wireless communication system using AAL5. As shown, once a flow control apparatus of the present invention turns on, the flow control apparatus checks data delivered from the upper layer applications at step S501 and determines whether the data is real-time sensitive (voice) or loss sensitive (data) at step S502.

If the data is loss sensitive, the flow control apparatus delivers the data to a flow control function 45 so as to enter a flow control procedure at step S503. Otherwise, if the data is real-time sensitive, the flow control apparatus directly sends the data to lower layers at step S504.

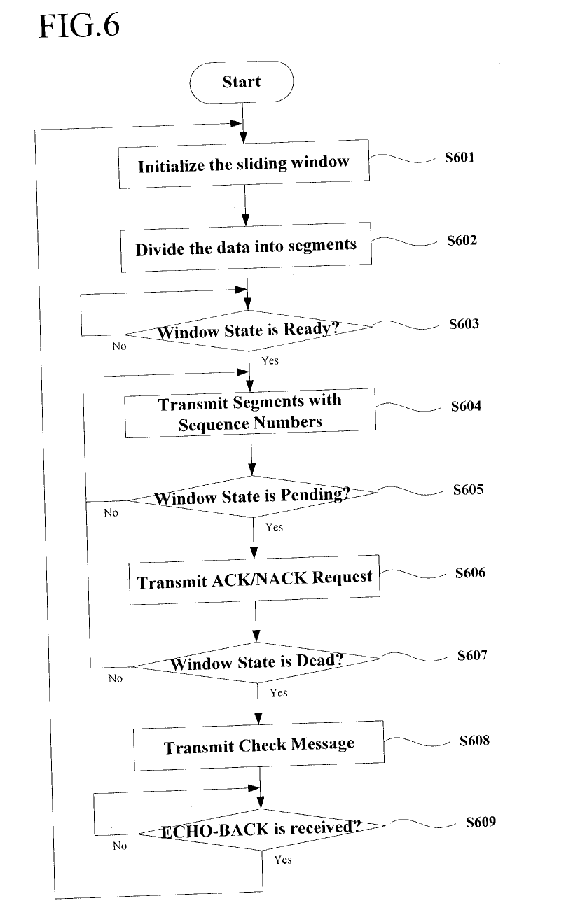

FIG. 6 is a flowchart illustrating the flow control procedure of FIG. 5. As shown in FIG. 6, if the flow control apparatus enters the flow control procedure, the flow control function 45 initializes sliding window at step S601 and divides the data into units of segments at step S602. The flow control function 45 then checks whether the window is in the Ready State at step S603, transmits segments with unique sequence numbers preferably in an amount which is as much as the window size can accommodate when the window is in the Ready State, and stores duplicates of the segments at step S604. After sending the segments, the flow control function 45 waits for acknowledgement messages in response to the segments and determines whether or not the window is in the Pending State at step S605. If the ACK/NACK message is received, the flow control function 45 transmits next segments according to ACK, discards the associated duplicates, and retransmits the duplicates according to NACK. On the other hand, the ACK/NACK message is not received in a predetermined timeout limit, the flow control function 45 transmits an ACK/NACK request message at step S606. The ACK/NACK request message is repeatedly transmitted a predetermined number of times if there is no ACK/NACK message in response to the ACK/NACK request message.

Sequentially, the flow control function 45 determines whether or not the window is in a Dead State at step S607. If ACK/NACK message is received in response to the ACK/NACK request message, the flow control function 45 discards the duplicate of the segment reported by the ACK message and transmits next segments, and retransmits the duplicate of the segment reported by NACK message. On the other hand, the ACK/NACK message is not received within a predetermined timeout limit, the flow control function 45 determines that the window is in the Dead State so as to transmit a Check message at step S608, and waits for an Echo-Back message in response to the Check message at step S690. The Check message is repeatedly transmitted several times if the Echo-Back message is not received within a predetermined time. On the other hand, if the Echo-Back message is received, the flow control function 45 reinitializes the sliding window.

While this invention has been described in connection with what is presently considered to be a practical and preferred embodiment, it is to be understood that the invention is not limited to the disclosed embodiments. On the contrary, the present invention is intended to cover various modifications and equivalent arrangements included within the spirit and scope of the appended claims.

As described above, in the flow control apparatus and method for wireless communication system using AAL5 as the Adaptation Layer according to the present invention, flow control is selectively performed according to the traffic types (e.g., real time sensitive and loss sensitive) or upper layer applications such that it is possible to maximize the system performance.

Also, since the flow control apparatus and method of the present invention flexibly manages the sliding window according to the voice-data traffic ratio, it is possible to efficiently control the traffic flow even when the data traffic amount is less than that of the voice traffic.

Furthermore, the flow control apparatus and method of the present invention adopts an improved sliding window algorithm which periodically checks the network situations such that it is possible to quickly troubleshoot the network problems such as the link breakage and malfunctions of the system.

The foregoing embodiments and advantages are merely exemplary and are not to be construed as limiting the present invention. The present teaching can be readily applied to other types of apparatuses. The description of the present invention is intended to be illustrative, and not to limit the scope of the claims. Many alternatives, modifications, and variations will be apparent to those skilled in the art. In the claims, means-plus-function clauses are intended to cover the structures described herein as performing the recited function and not only structural equivalents but also equivalent structures.

What is claimed is:

1. A flow control apparatus for a mobile communication system, comprising:
a traffic-type recognition module which determines a traffic type of a payload from a first layer; and
a flow control module which controls flow of the payload based on the traffic-type determined by the traffic-type recognition module.

2. The apparatus of claim 1, wherein the traffic-type recognition module delivers the payload to the flow control module when the traffic-type of the payload is a first traffic type and directly transfers the payload to a second layer when the traffic type of the payload is a second traffic-type.

3. The apparatus of claim 2, wherein the first traffic type is a loss-sensitive type.

4. The apparatus of claim 3, wherein the loss-sensitive type payload is a data-based payload.

5. The apparatus of claim 2, wherein the second traffic type is a real-time sensitive type.

6. The apparatus of claim 3, wherein the real-time sensitive type payload is a voice- or video-based payload.

7. The apparatus of claim 1, wherein the flow control module controls the traffic flow based on a modified sliding window algorithm.

8. The apparatus of claim 1, wherein the flow control module includes:
a transmission buffer which temporarily stores the payload from the first layer until receiving an acknowledgement after transmission of the payload;
a transmission window which adjusts a transmission amount of the payload;
a reception buffer which temporarily stores received payloads until a first layer data unit is completed with the received payloads;
a reception window which adjusts a reception amount of the payload;
a window management module which controls the transmission buffer, transmission window, reception buffer, and reception window based on a network state.

9. The apparatus of claim 8, wherein the window management module periodically checks states of the transmission and reception windows and transmits system messages according to the states of the transmission and reception windows.

10. The apparatus of claim 9, wherein the state of the window is one of a ready state, pending state, and dead state.

11. The apparatus of claim 10, wherein the window management module controls transmission of the payload when the transmission window is in the ready state.

12. The apparatus of claim 10, wherein the window management module periodically generates and transmits an acknowledgement request message when the transmission window is in the pending state.

13. The apparatus of claim 12, wherein the transmission window enters the ready state when an acknowledgement message is received in response to the acknowledgement request message.

14. The apparatus of claim 10, wherein the window management module periodically generates and transmits a check message.

15. The apparatus of claim 14, wherein the transmission window is reinitialized when an echo-back message is received in response to the check message.

16. A flow control apparatus for a mobile communication system, comprising:
a traffic type recognition module winch determines a traffic type of a payload from a first layer;
a flow control module which controls flow of the payload based on the traffic type determined by the traffic-type recognition module; and
a second layer interface module which interfaces with an ATM Adaptation Layer type 5 (AAL5) and allows the flow control apparatus to communicate the payload with the AAL5.

17. The apparatus of claim 16, wherein the traffic type recognition module delivers the payload to the flow control module when the traffic type of the data is a first traffic type and directly transfers the payload to the second layer when the traffic type of the payload is a second traffic type.

18. The apparatus of claim 17, wherein the first traffic type is loss-sensitive.

19. The apparatus of claim 18, wherein the second traffic type is real-time sensitive.

20. The apparatus of claim 19, wherein the loss-sensitive type payload is a data-based payload and the real-time sensitive type payload is a voice- or video-based payload.

21. The apparatus of claim 19, wherein the flow control module controls the traffic flow based on a modified sliding window algorithm.

22. A flow control method for a mobile communication system, comprising:
receiving data from a first layer;
checking a traffic type of the data; and
controlling transmission of the data according to the traffic type of the data.

23. The method of claim 22, wherein the traffic type is one of a real-time sensitive type and a loss-sensitive type.

24. The method of claim 23, wherein controlling transmission includes:
forwarding the data to an AAL5 Adaptation Layer when the traffic type of the data is real-time sensitive; and
entering a flow control procedure when the traffic type of the data is loss-sensitive.

25. The method of claim 24, wherein the flow control procedure includes:
initializing a sliding window;
checking a state of the sliding window; and
adjusting the data transmission according to the state of the sliding window.

26. The method of claim 25, wherein adjusting the data transmission includes transmitting, the data in at least one segment with a unique sequence number when the sliding window is in a ready state.

27. The method of claim 26, wherein the sliding window maintains the ready state when an ACK/NACK message is received in response to a previously transmitted segment within a first timeout period.

28. The method of claim 27, wherein adjusting the data transmission further includes transmitting ACK/NACK request message when the sliding window is in a pending state.

29. The method of claim 28, wherein the sliding window enters the pending state when an ACK/NACK message is not received in response to a previously transmitted segment within the first timeout period.

30. The method of claim 29, wherein adjusting the data transmission includes transmitting a check message when the sliding, window is in a dead state.

31. The method of claim 30, wherein the sliding window enters the dead state when an ACK/NACK message is not received in response to the ACK/NACK request message within a second timeout period.

32. The method of claim 31, wherein the sliding window is reinitialized when an echo-back message is received in response to the check message within the second timeout period.
